(19) United States
(12) Patent Application Publication
(10) Pub. No.: US 2012/0166115 A1
(43) Pub. Date: Jun. 28, 2012

(54) PLATFORM, SYSTEM AND METHOD FOR ENERGY PROFILING

(75) Inventor: Costa Apostolakis, Locust Grove, VA (US)

(73) Assignee: NEXGRID, LLC, Locust Grove, VA (US)

(21) Appl. No.: 13/335,073

(22) Filed: Dec. 22, 2011

Related U.S. Application Data
(60) Provisional application No. 61/426,556, filed on Dec. 23, 2010.

(51) Int. Cl. G06F 19/00; G01R 21/00

(52) U.S. Cl. 702/62

(57) ABSTRACT

An energy usage management platform is provided for remotely managing energy usage of multiple end user devices or appliances, including a smart grid network with an energy data server adapted to manage multiple electric device energy usage profiles, and an electric meter for transmitting electricity usage data to the energy data server, thereby enabling the energy data server to monitor energy usage of identified electric devices, wherein there is substantially no requirement to install an electricity usage sensor on the specific electric devices.

### CROSS REFERENCE TO RELATED APPLICATIONS

This application claims priority from U.S. Provisional Patent Application No. 61,426,556, filed 23 Dec. 2010, entitled “SYSTEM AND METHOD FOR ENERGY PROFILING”, which is incorporated in its entirety herein by reference.

### FIELD OF THE INVENTION

The present invention relates to methods and devices useful in enhancing energy usage. Specifically, embodiments of the present invention relate to systems and methods that provide means for automated energy management.

### BACKGROUND OF THE INVENTION

Many countries today, primarily those in the developed world, are making significant efforts to try convert or upgrade their existing electric power grids to smart grids.

Over the past 50 years, electricity networks have not kept pace with modern challenges, and these “smart grids” are intended to handle these more recent challenges such as: security threats, growing reliance on alternative power generation sources, conservation goals that seek to lessen peak demand surges during the day so that less energy is wasted in order to ensure adequate reserves, handling high demand for an electricity supply that is un-interruptible, facilitating digitally controlled devices that can digitally and/or remotely control energy demand etc. A smart grid needs to be able to handle these challenges to ensure energy supply reliability and prevent more common recent occurrences such as power quality disturbances, blackouts, and brownouts.

Smart grid technologies have also advanced a lot since the initial attempts at using electronic control, metering, and monitoring. In the 1980s, Automatic meter reading was used for monitoring loads from large customers, and this evolved into the Advanced Metering Infrastructure of the 1990s, which included meters adapted to store electricity usage data. More recent smart meters can add continuous communications so that monitoring can be done substantially in real time, and can be used as a gateway to remotely interact with smart devices and “smart sockets” in the home.

Monitoring and synchronization of wide area networks were revolutionized in the early 1990s. For example, the Bonneville Power Administration expanded its smart grid research with prototype sensors that are capable of very rapid analysis of anomalies in electricity quality over very large geographic areas. The culmination of this work was the first operational Wide Area Measurement System (WAMS) in 2000.

### SUMMARY OF THE INVENTION

There is provided, in accordance with an embodiment of the present invention, a platform, system, and method for energy usage management. According to some embodiments of the present invention, the system may include a utility portal module adapted to enable a power utility to manager a smart grid; an energy data server adapted to manage appliance energy usage profiles, the energy data server being communicatively associated with the utility portal; an energy profiling module adapted to generate device energy usage profiles; and an energy data server database to store device energy usage profile related data.

In accordance with some embodiments, an energy usage management platform is provided for remotely managing energy usage of multiple end user devices or appliances, including a smart grid network with an energy data server adapted to manage multiple electric device energy usage profiles; and an electric meter for transmitting electricity usage data to the energy data server, thereby enabling the energy data server to monitor energy usage of identified electric devices; wherein there is substantially no requirement to install an electricity usage sensor on the electric devices.

In some embodiments, the energy usage management platform further includes software running on an end user application, to enable end user interfacing with said energy data server.

In some embodiments the energy usage management platform may further include a utility portal module proving interactive access to the energy data server by a power Utility.

In a further embodiment, the energy usage management platform's smart grid network may further include a consumer portal module proving interactive access to the energy data server by an end user.

In some embodiments, the energy usage management platform's electric meters are connected via Zigbee protocol to the smart grid network.

In some embodiments, the energy usage management platform is communicatively coupled to a wireless network, where the wireless network is the medium through which the respective electric meters communicate to the smart grid.

According to some embodiments, the energy usage management platform further comprises an energy profiling management module, for enabling device profile generation for devices connected to the smart grid network.

In accordance with some embodiments, a smart grid network adapted to enable remote device energy management, is provided, including an energy profiling module adapted to generate device energy usage profiles for multiple end user devices connected to the smart grid; an energy data server adapted to manage the device energy usage profiles; and an energy data server database to store device energy usage profile related data.

According to some embodiments, the energy data server is connected to electric meter devices via a wireless network.

In further embodiments, the wireless network is a Zigbee powered network.

In further embodiment the energy data server is connected to a utility portal module adapted to enable a power utility to manager the smart grid.

In still further embodiments, a consumer portal module may be communicatively connected to the energy data server, to enable an end user to interact with the energy data server.

In other embodiments, the energy data server is adapted to monitor the activity of multiple end user device electric meters in accordance with the respective device profiles of the multiple end user devices, to determine energy usage anomalies.

In accordance with some embodiments, a method is provided for enabling remote energy profiling in a smart grid network, including running an energy audit on a device type; assigning to each device type an energy profile; storing results of the energy audit on an energy data database; monitoring energy usage data in the smart grid network; identifying the energy profile within an energy usage data; comparing energy usage associated with a device with the energy profile associated with such a device type; and identifying anomalies in energy usage for the selected device type in a specific location.

According to some embodiments, the method my include generating a report based on the comparison. In some embodiments an alert may be generated if an anomaly is identified. In still further embodiments corrective action may be taken, optionally automatically, if an anomaly is identified.

In accordance with some embodiments the profiling may be executed substantially without installing any additional equipment on a device being monitored.

### BRIEF DESCRIPTION OF THE DRAWINGS

The principles and operation of the system, apparatus, and method according to the present invention may be better understood with reference to the drawings, and the following description, it being understood that these drawings are given for illustrative purposes only and are not meant to be limiting, wherein:

FIG. 1 is a schematic block diagram of a smart grid system integrating energy profiling, according to some embodiments; and

FIGS. 2A and 2B are flowcharts illustrating examples of processes of energy profiling in a smart grid system, according to some embodiments.

It will be appreciated that for simplicity and clarity of illustration, elements shown in the drawings have not necessarily been drawn to scale. For example, the dimensions of some of the elements may be exaggerated relative to other elements for clarity. Further, where considered appropriate, reference numerals may be repeated among the drawings to indicate corresponding or analogous elements throughout the serial views.

### DETAILED DESCRIPTION OF THE INVENTION

The following description is presented to enable one of ordinary skill in the art to make and use the invention as provided in the context of a particular application and its requirements. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed. In other instances, well known methods, procedures, and components have not been described in detail so as not to obscure the present invention.

The phrase “energy profile” as used herein may encompass energy usage, energy signature, energy reading, or other meanings relating to the usage of energy by a system, product or appliance, and optionally the measurement of that energy usage over time to determine certain characteristics about the device(s) consuming of electricity. The term “device” as used herein may refer to electric devices, appliances, machines etc. that may be monitored for energy usage.

It would be highly advantageous to have a way to remotely monitor specific electric devices and appliances etc. to be able to better forecast, control and manage energy usage from a significant number of energy using devices. Embodiments of the present invention enable remote energy profiling of electric devices and appliances etc., and usage of the energy profiling data for aiding energy efficiency and identification of electric device failures, without having any measurement device attached to specific devices being monitored.

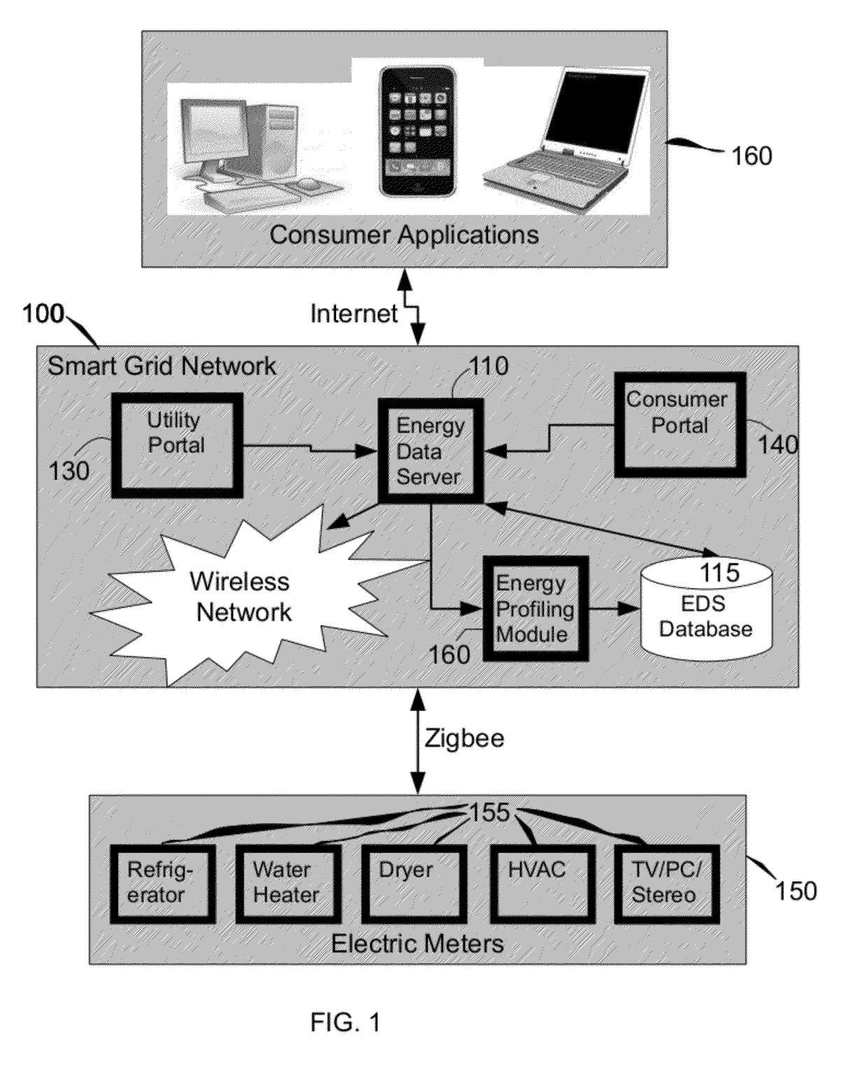

Reference is now made to FIG. 1, which is a schematic block diagram of a Smart Grid network 100, according to some embodiments. As can be seen in FIG. 1, network 100 may be, for example, an EcoNet type Network, wherein smart energy management units are set up in a wireless or hybrid wireless network, such as that of Nexgrid LLC (www.nexgrid.net). In one example, a multimesh type smart grid network may be used as part of the information infrastructure of network 100, as described in detail in US patent application Ser. No. 13,285,430, by the same inventor, which is hereby incorporated fully by reference. Of course, other smart grid networks and communication infrastructures may be used. Smart Grid network 100 may include, for example, a wireless communications network 105, and Energy Data Server (EDS) 110, EDS database 115, a Utility portal 130, and a Consumer portal 140. In some embodiments EDS Server 110 is connected to Utility portal 130, Consumer portal 140 and EDS database 115 optionally via a VPN or other secure data transfer means; however other network communications devices, systems and protocols may be used. Smart Grid system 100 is adapted to connect to and interact with electric meter devices 150, for example, standard electric meters that measure electricity usage from multiple devices, appliances or machines etc., and optionally from specific energy usage meters such as water meter or energy metering devices (gas, electric), thermostats, meters, switches etc. Optionally, meters 150 may be wireless communications supporting devices, which are communicatively coupled to appliances, or electronic devices to wireless network 105. Smart Grid network 100 is further adapted to connect wireless network 105 to multiple consumer or end user applications 160 via the Internet or alternative data communications element. For example, desktops, notebooks, smart phones, or other computing or communications devices that may be used to manage, access and/or control end devices 155. End devices such as refrigerators, ovens, plasma or LCD televisions, electric clothes dryers, consumer devices etc. are connected to the power system that is connected to the meter(s) 150 in the communication network.

Energy Data Server (EDS) 110 may include an interface for at least two-way communications with end devices 155. EDS database 115 may include a database for tracking the health or status of the communication network as well as various data elements captured from end devices 155. EDS 110 includes or is coupled to an Energy profiling Module (EPM) 160, which in turn is coupled to EDS Database 115.

EPM 160 may include code, script, programs, algorithms and/or instructions for processing energy usage data from end devices 155, received via energy measurement meters, including standard digital meters or other digital electric meters. For example, EPM 160 may run a program to map out a curve of how the energy usage changes over time, thereby allowing the EDS or alternative energy management system to determine if/when a specific device is being turned on or off. In another example, EPM 160 allows an operator to determine how much power is consumed by one or more devices, and may compare that curve to other similar devices in the EPM database 165, to determine whether something may be exceptional and thereby indicative of a problem, for example if the device is consuming too much energy for what it does etc. It is noted that EPM may profile data from substantially any source. In some embodiments EPM may be decoupled from the source or destination of data input and output, such that EPM is adapted to run all of the logic without particular regard for the smart grid system (such as EDS) or the portal being used.

Utility portal 130 may include a user interface that may be web-based and may enable grid network management and interaction (e.g., for a Utility company) with the core functionality provided by the EDS server (e.g., network and grid management, monitoring etc.). Consumer portal 140 may include a user interface for enabling the end consumer or remote user to monitor and/or manage energy usage. According to some embodiments, Consumer portal 140 may be used for reviewing and/or otherwise interacting with energy demand statistics or information.

According to some embodiments, EDS 110 may connect to end devices 155, via standard electric meter(s) 150, in such a way so as to retrieve successive reads from devices in very small increments. In some cases, increments may be 1 second or smaller, and when calculated with, for example, current 2.5 second round trip times, reads may be collected at, for example, 5 second increments. Of course, smaller or larger increments may be used. Through this process, EDS 110 is able to collect reads for a period of time and determine when a specific end device is turning on in a remote location, such as a home. Since all energy usage devices follow a certain profile as they turn on and run, this profile data may be recorded and processed by energy profiling server 112, in communication with energy profiling database 113, thereby enabling Smart Grid system 100 to determine how much power a specific device consumes, substantially without having to install any additional hardware inside the remote location. Furthermore, Smart Grid system 100 is adapted to identify inefficient devices, and in some embodiments, may provide best practice recommendations, such as purchase recommendations to reduce energy costs, along with specific payback period calculations. For example, a consumer may be advised to buy a $200 energy efficient water heater, which will be paid off in an estimated six months by the corresponding energy savings the consumer may be expected to achieve.

In accordance with some embodiments of the present invention, a method is provided for enabling remote energy profiling in a smart grid network. The method may include, for example, running an energy profiling module to execute an energy audit on a device type, such as an electronic appliance or device, to develop a device type energy usage signature or profile. For example, appliance types such as refrigerators, washers, dryers, water heaters, heating, ventilation, and air conditioning (HVAC) have been shown to display distinct curves relating to their energy usage, determined through taking demand readings periodically. In further examples, such distinct curves, signatures or profiles may be used for other appliance or device types, and even particular products within the appliance or device type categories, such as devices of particular producers, sizes, versions, dates of production, etc. Once a profile is identified or otherwise derived, these profiles and/or additional suitable energy usage data may be transferred or otherwise integrated into an energy data database, for subsequent storage and usage. In a further step, an energy usage server is set up in a smart grid network, to monitor and/or manage energy usage profiles. Typically such a server is set up to be in communication with a power Utility portal, to be able to monitor and/or process energy usage data being accessed by the Utility portal. The energy data server is further coupled to the energy data database, and to the energy profiling management (EPM) module. During subsequent operation of the smart grid, the energy data server monitors energy usage data in the smart grid network, to identify device profiles, in accordance with device profile data on the energy data database. For identified profiles, the energy data server compares actual energy usage data associated with a specific device with the energy signature or profile associated with such a device type. The energy data server may subsequently generate a report, alert, instruction etc. based on the comparison. It is noted that in accordance with some embodiments, the above described device profiling is executed substantially without installing any additional equipment on a specific device to be monitored.

According to some embodiments, the energy data server may generate an alert if an anomaly is identified. For example, once the system identifies an exception and determines that such an exception is over a threshold that makes it worthy of alerting a user or controller etc., such an exception, whether as data, an alert, a suggestion, or a warning etc. may be sent to a user or controller etc., for example, in an email, SMS, Tweet, instant message etc. In further embodiments the energy data server may take corrective action if an anomaly is identified, or more particularly, if the anomaly is beyond a defined threshold indicating an urgency to take action. For example, if a critical problem has been identified, the smart grid might automatically shut down power supply to the plug to which a problematic device is attached, or power to the plug, circuit, building etc. may be reduced, increased or otherwise controlled.

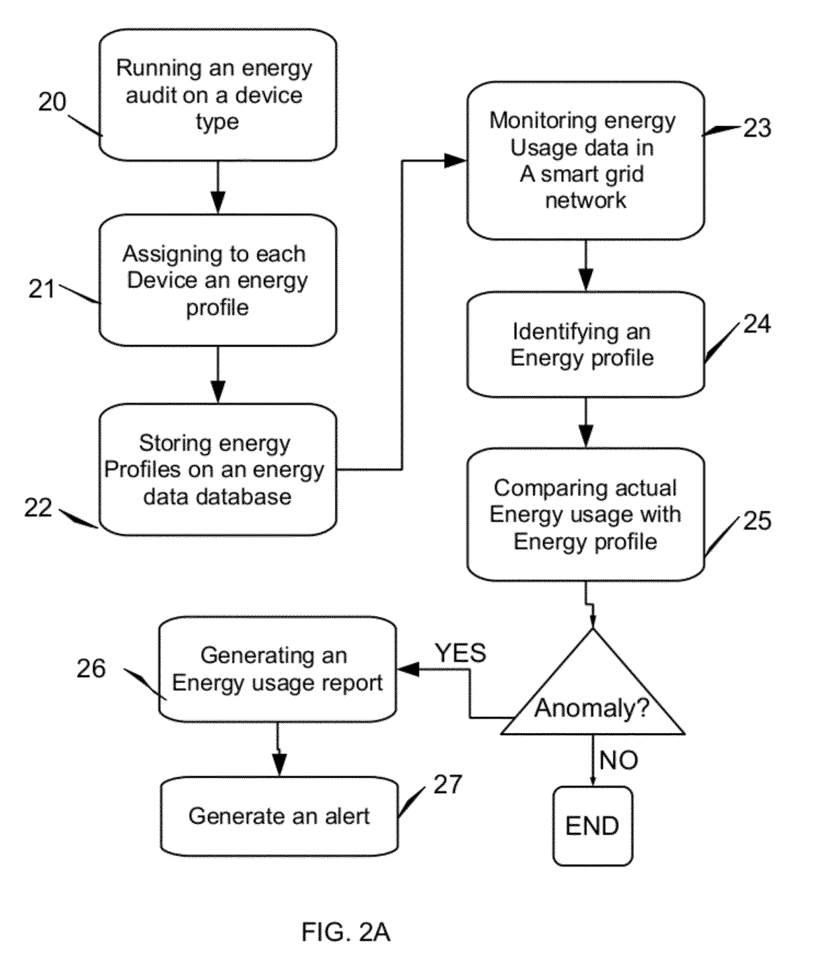

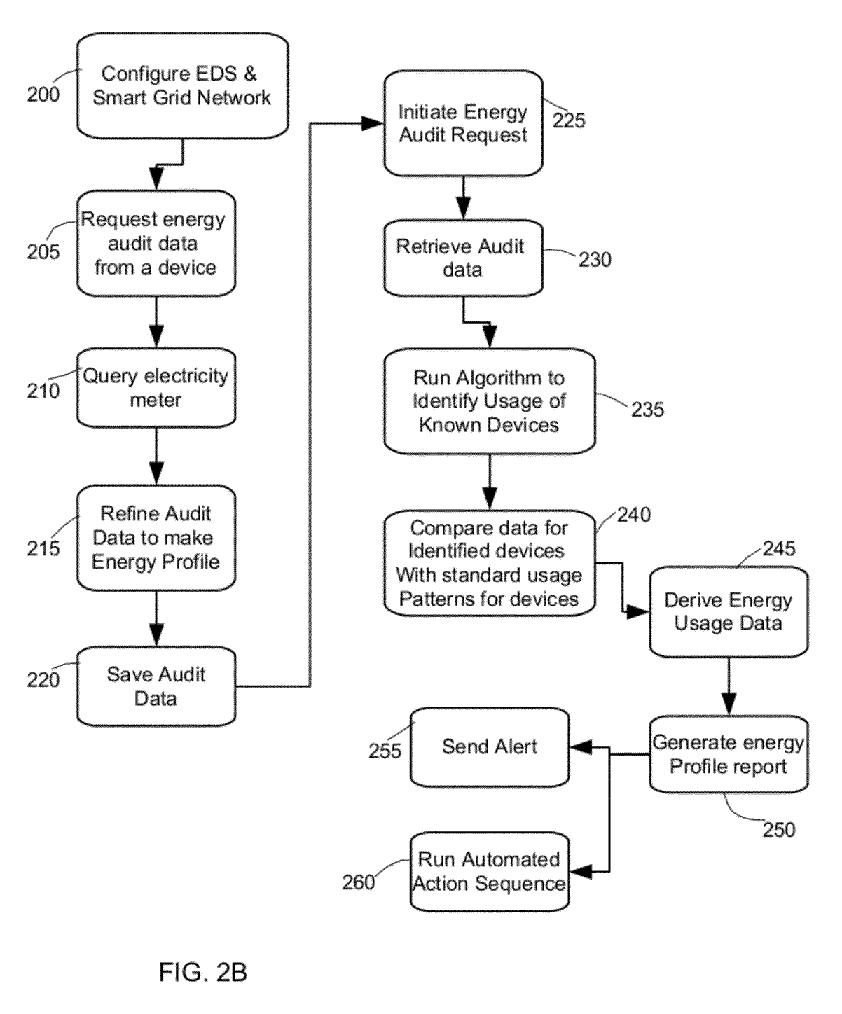

Reference is now made to FIGS. 2A and 2B, which are flowcharts illustrating examples of processes of energy profiling in a smart grid system, according to some embodiments. Reference is now made to FIG. 2A, which illustrates an example of elements related to the setup and execution of remote energy profiling. At block 20, an energy audit may be run on a device type, to identify its energy usage characteristics. At block 21 each device type is assigned an energy profile, which is stored, at block 22, on an energy data database. At block 23 the smart grid network monitors energy usage data in the network. At block 24 the energy data server attempts to identify, from the energy usage data, energy profiles of devices being run in the smart grid network. In some examples, such an identification request may be initiated from either a consumer or the Utility. At block 25, energy data server compares actual energy usage patterns of identified energy profiles to expected energy usage patterns of recorded energy profiles, to seek out patterns, exceptions, etc. that may indicate problems, limitations or other causes for concern, learning, planning or action. At block 26, if an exceptional pattern, exception, anomaly etc. is identified in connection with an energy profile, an energy usage report may be generated, and in some or all cases, at block 27, an alert, warning or other action may be generated and optionally transmitted to the device user. In still further cases the system may enable the power Utility to take proactive action in certain situations, such as shutting down or limiting the power supply to a problematic device on the circuit or grid.

Reference is now made to FIG. 2B, which shows a work flow for an example of generating an energy profile and an energy profile report or response, in accordance with some embodiments. As can be seen in the figure, at step 200, a smart grid system is configured, such as a typical smart grid network or an EcoNet type Network, wherein smart energy management units are set up in a wireless or hybrid wireless network, such as that of Nexgrid LLC (www.nexgrid.net). At step 205 an energy audit data gathering event is requested by the energy profile management (EPM) module, the request being sent to one or more energy measurement devices, such as a meter/switch, being in communicative connection with one or more end user devices or appliances. Of course, the data gathering may be requested by additional or alternative sources. At step 210 a meter is queried until data is provided to enable the EPM to execute code to complete an energy audit or calculation. Once the audit is complete, at step 215, the audit information may be refined, edited, refined etc., and once complete, it may be saved at step 220, in an energy data server database, and thereafter the audit data may be made available to the EDS.

At step 225, optionally upon request by the EDS/EPM, an energy audit request may be initiated, for example from a user, Utility, operator, or an automated system. At step 230 the EPM or alternative energy management system may retrieve data from a data meter, which may include energy usage data from one more devices and/or appliances, from internal and/or external sources. At step 235, an energy profiling algorithm may be executed on the retrieved data, whether internal or external data, to identify know devices in accordance with pre-configured or pre-identified device profiles. At step 240 the typical energy rates, reflected in device profiles and/or usage patterns may be compared with the audited data gathered from actual events. At step 245 the results of the comparisons are derived, herein referred to as the “energy data”. At step 250 an energy profile report is generated, which may be used in step 255, for example, to notify an operator or user as to potential device/appliance problems etc. In some cases, at step 260, automated or semi-automated actions may be taken to change, limit or stop energy provision to a problematic point, device, circuit etc.

In accordance with some embodiments, Energy Profiling module 160 may initiate a read function for a specific end device, and may begin logging subsequent reads at a selected interval, for example every 1-5 seconds. Logs may typically be maintained in Energy Profiling Database 165. Energy Profiling module 160 may run a program or code to measure the changes in device energy usage over various time frames to determine the slope of the resulting energy usage curve at various given points, thereby providing a “picture” of the general shape of a specific device turning on and/or running. In one example, a device being used may form an energy usage sine wave, the first derivative of which can provide the slope of that curve at that point. Energy Profiling Database 165 may thereby identify unique energy profiles or fingerprints of selected energy usage devices. Subsequently when monitoring a selected end device, Energy Profiling module 160 may compare the specific device's usage slopes, characteristics, signature or profile (hereinafter referred to as a “smart energy profiles”) to pre-recorded smart energy profiles for a substantially similar device, which have been previously studied, identified and/or recorded, optionally in a lab environment. In this way, Energy Profiling module 160 may enable real time or near real time data relating to specific device performance, optionally without installing any additional equipment on each appliance or device being monitored. Of course, during the above process there must be an allowance for other devices that are turning on in the remote location. Therefore, an allowance may be made for reasonable tolerances in the readings, to ensure that the energy profiling calculations do not get overly biased or distorted by non substantial interferences, such as a light turning or another appliance turning on in or substantially close to the remote location.

In further embodiments key statistics of end device energy usage may be stored, processed and used, to help identify patterns for a device turning on or off, or for the running of such a device. Such data may be stored in the Energy Profiling Database 165. When such statistics are calculated over time, Energy Profiling module 160 may be adapted to make recommendations to end users about the user's energy using devices. For example, Energy Profiling module 160 may indicate which appliances are running efficiently or inefficiently, which devices should be replaced, and how much it is costing the user to run them. Furthermore, Energy Profiling module 160 may help in making recommendations on running devices at a different time of the day if applicable, or running in a different way, or less frequently if possible etc. Since Energy Data Server (EDS) 110 is a learning system, it may continue to grow in scope, breadth and accuracy as more smart profiles are added to Energy Profiling database 113, and as the smart grid system uses higher data communications bandwidths. Of course, any combination of the above steps may be implemented. Further, other steps or series of steps may be used.

According to some embodiments, the usage of substantially real time Energy Profiling, optionally without requiring installing any additional equipment on each appliance or device being monitored, helps build a framework for facilitating energy usage management for multiple Smart Grid Applications. In some implementations the derivation of real time Energy Profiles for end devices is PHY independent and thus transportable by Wireless 802.11 or other wireless suitable communication protocols.

The foregoing description of the embodiments of the invention has been presented for the purposes of illustration and description. It is not intended to be exhaustive or to limit the invention to the precise form disclosed. It should be appreciated by persons skilled in the art that many modifications, variations, substitutions, changes, and equivalents are possible in light of the above teaching. It is, therefore, to be understood that the appended claims are intended to cover all such modifications and changes as fall within the true spirit of the invention.

What is claimed is:

1. An energy usage management platform, comprising:
a smart grid network including an energy data server adapted to manage multiple electric device energy usage profiles; and
an electric meter for transmitting electricity usage data to said energy data server, thereby enabling said energy data server to monitor energy usage of identified electric devices;
wherein there is substantially no requirement to install an electricity usage sensor on said electric devices.

2. The energy usage management platform of claim 1, wherein said smart grid network further includes a utility portal module proving interactive access to said energy data server by a power Utility.

3. The energy usage management platform of claim 1, further comprising software running on an end user application, to enable end user interfacing with said energy data server.

4. The energy usage management platform of claim 1, wherein said electric meters are connected via Zigbee protocol to said smart grid network.

5. The energy usage management platform of claim 1, wherein said energy data server is communicatively coupled to a wireless network, said wireless network being the medium through which the respective electric meters communicate to said smart grid.

6. The energy usage management platform of claim 1, further comprising an energy profiling module, for enabling device profile generation for devices connected to said smart grid network.

7. A smart grid network adapted to enable remote device energy management, comprising:
an energy profiling module adapted to generate device energy usage profiles for multiple end user devices connected to the smart grid;
an energy data server adapted to manage said device energy usage profiles; and
an energy data server database to store device energy usage profile related data.

8. The network of claim 7, wherein said energy data server is connected to electricity meter devices via a wireless network.

9. The network of claim 8, wherein said wireless network is a Zigbee powered network.

10. The network of claim 7, further comprising a utility portal module adapted to enable a power utility to manager said smart grid;

11. The network of claim 7, further comprising a consumer portal module, communicatively connected to said energy data server, to enable an end user to interact with said energy data server.

12. The network of claim 7, wherein said energy data server is adapted to monitor the activity of multiple end user device electric meters in accordance with the respective device profiles of said multiple end user devices, to determine energy usage anomalies.

13. A method for enabling remote energy profiling in a smart grid network, comprising:
running an energy audit on a device type;
assigning to each device type an energy profile;
monitoring energy usage data in the smart grid network;
identifying said energy profile within said energy usage data;
comparing energy usage associated with a device with said energy profile associated with such a device type; and
identifying anomalies in energy usage for said selected device type in a specific location.

14. The method of claim 13, comprising generating a report based on said comparison.

15. The method of claim 13, comprising generating an alert if an anomaly is identified.

16. The method of claim 13, comprising taking a corrective action if an anomaly is identified.

17. The method of claim 13, wherein said profiling is executed substantially without installing any additional equipment on a device being monitored.
